(19) United States
(12) Patent Application Publication
(10) Pub. No.: US 2019/0081275 A1
(43) Pub. Date: Mar. 14, 2019

(54) DISPLAY DEVICE AND MANUFACTURE METHOD THEREOF

(71) Applicant: BOE TECHNOLOGY GROUP CO., LTD., Beijing (CN)

(72) Inventor: Zhiqiang JIAO, Beijing (CN)

(73) Assignee: BOE TECHNOLOGY GROUP CO., LTD., Beijing (CN)

(21) Appl. No.: 16/117,537

(22) Filed: Aug. 30, 2018

(30) Foreign Application Priority Data
Sep. 14, 2017 (CN) 201710829373.3

(51) Int. Cl. H01L 51/52; H01L 51/56; H01L 27/32

(52) U.S. Cl. CPC H01L 51/5253; H01L 51/56; H01L 2227/323; H01L 27/3211; H01L 27/3246; H01L 27/322

(57) ABSTRACT

A display device and a manufacture method thereof are provided. The display device includes a display panel and a film package component on the display panel. The film package component includes a first water blocking material layer on the display panel, a color filter layer on the first water blocking material layer, and a second water blocking material layer on the color filter layer.

### CROSS REFERENCE TO RELATED APPLICATION

The present application claims priority to the Chinese patent application No. 201710829373.3, filed on Sep. 14, 2017, the entire disclosure of which is incorporated herein by reference as part of the present application.

### TECHNICAL FIELD

Embodiments of the present disclosure relate to a display device and a manufacture method thereof.

### BACKGROUND

OLED (Organic Light Emitting Diode) display devices have a series of advantages such as self-luminescence, high contrast, high definition, wide viewing angle, low power consumption, fast response, low manufacturing cost and so on, and have become one of the key development trends of new generation display devices, and therefore the OLED display devices attract more and more attention.

Generally, full color display of an OLED display device is achieved by a method in which red, green and blue pixels are arranged side by side, or by a method in which white organic light emitting diodes are combined with color filter layers.

### SUMMARY

At least one embodiment of the present disclosure provides a display device, the display device comprises a display panel and a film package component on the display panel, and the film package component comprises a first water blocking material layer on the display panel, a color filter layer on the first water blocking material layer, and a second water blocking material layer on the color filter layer.

For example, in the display device provided by at least one embodiment of the present disclosure, a material of the first water blocking material layer comprises an inorganic material; and/or a material of the second water blocking material layer comprises an inorganic material.

For example, in the display device provided by at least one embodiment of the present disclosure, the inorganic material comprises silicon nitride, silicon oxide, silicon oxynitride, titanium oxide, zirconium oxide, tantalum oxide, barium titanate, neodymium oxide, aluminum oxynitride, zirconium oxynitride, tantalum oxynitride, yttrium oxynitride or neodymium oxynitride.

For example, in the display device provided by at least one embodiment of the present disclosure, a thickness of the first water blocking material layer ranges from 100 nm to 1000 nm.

For example, in the display device provided by at least one embodiment of the present disclosure, the second water blocking material layer is 200 nm-300 nm thicker than the first water blocking material layer.

For example, in the display device provided by at least one embodiment of the present disclosure, a thickness of the color filter layer ranges from 1 μm to 3 μm.

For example, in the display device provided by at least one embodiment of the present disclosure, the color filter layer comprises a plurality of color filters of different colors in a same layer, and an interval is between color filters of different colors; and a stack layer of color filters of at least two colors is at a position of the interval; alternatively, the position of the interval corresponds to an opaque portion of a pixel definition layer of the display panel.

For example, in the display device provided by at least one embodiment of the present disclosure, the stack layer of color filters of at least two colors comprises two color filters of two different colors, and the two different colors are colors of two color filters that are adjacent to the interval.

For example, in the display device provided by at least one embodiment of the present disclosure, the display panel is an organic light emitting diode (OLED) display panel, and a light emitting layer of the OLED display panel is a white light emitting layer or comprises a plurality of color light emitting layers.

For example, in the display device provided by at least one embodiment of the present disclosure, the film package component further comprises a first planarization layer between the color filter layer and the first water blocking material layer, and/or a second planarization layer between the color filter layer and the second water blocking material layer.

At least one embodiment of the present disclosure provides a manufacture method of a display device, and the manufacture method comprises: providing a display panel; and forming a film package component on the display panel; forming the film package component comprises: forming a first water blocking material layer on the display panel; forming a color filter layer on the first water blocking material layer; and forming a second water blocking material layer on the color filter layer.

For example, the manufacture method of a display device provided by at least one embodiment of the present disclosure further comprises: forming a first planarization layer between the color filter layer and the first water blocking material layer, and/or forming a second planarization layer between the color filter layer and the second water blocking material layer.

For example, in the manufacture method of a display device provided by at least one embodiment of the present disclosure, the color filter layer is formed by an inkjet printing method.

For example, in the manufacture method of a display device provided by at least one embodiment of the present disclosure, forming the color filter layer comprises forming a plurality of color filters of different colors, and an interval is between color filters of different colors; and forming a stack layer of color filters of at least two colors at a position of the interval; alternatively, the interval is formed at a position corresponding to an opaque portion of a pixel definition layer of the display panel.

For example, in the manufacture method of a display device provided by at least one embodiment of the present disclosure, the color filter layer comprises a red color filter, a green color filter and a blue color filter, the stack layer of color filters of at least two colors comprises two color filters of two different colors and is formed at the position of the interval, the two different colors are colors of two color filters that are adjacent to the interval, and the stack layer of color filters and the two color filters that are adjacent to the interval are simultaneously formed.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a first schematic diagram of a display device provided by an embodiment of the present disclosure;

FIG. 2 is a second schematic diagram of a display device provided by an embodiment of the present disclosure;

FIG. 3 is third schematic diagram of a display device provided by an embodiment of the present disclosure;

FIG. 4 is a fourth schematic diagram of a display device provided by an embodiment of the present disclosure;

FIG. 5 is a fifth schematic diagram of a display device provided by an embodiment of the present disclosure;

FIG. 6 is a sixth schematic diagram of a display device provided by an embodiment of the present disclosure;

FIG. 7 is a flow diagram of a manufacture method of a display panel provided by an embodiment of the present disclosure;

FIG. 8 is a flow diagram of a manufacture method of a film package component in a display device provided by an embodiment of the present disclosure; and

FIGS. 9A-9B, FIGS. 9C1-9C4, and FIGS. 9D1-9D4 are sectional diagrams of a display device in a manufacture process provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

In order to achieve the full color display of the OLED display panel, the method used by the display panel in which the red, green and blue pixels are arranged side by side usually requires a combination with polarizers to achieve a good display effect; alternatively, the method used by the display panel in which white organic light emitting diodes are combined with color filter layers may cause problems such as small pixel aperture ratio of the display panel, color mixing and so on. For example, where white light is emitted from the bottom, the color filter layers are usually on an array substrate, and the aperture ratio is small; and where the white light is emitted from the top, the color filter layers are usually on a package cover, which is too far away from the light emitting layer, so the color mixing may occur during display.

At least one embodiment of the present disclosure provides a display device, the display device comprises a display panel and a film package component on the display panel, and the film package component comprises a first water blocking material layer on the display panel, a color filter layer on the first water blocking material layer, and a second water blocking material layer on the color filter layer.

At least one embodiment of the present disclosure provides a manufacture method of a display device, and the manufacture method comprises: providing a display panel; and forming a film package component on the display panel. Forming the film package component comprises: forming a first water blocking material layer on the display panel; forming a color filter layer on the first water blocking material layer; and forming a second water blocking material layer on the color filter layer.

In the display device provided by at least one embodiment of the present disclosure, the film package component can achieve a better filtering effect, and can alleviate light reflection of the surface of the display panel, and therefore the display panel can exhibit a good display effect without attaching a polarizer; in addition, the absence of the polarizer also contributes to a thin design of the display device.

The display device and the manufacture method thereof provided by the present disclosure are described below with reference to several specific embodiments.

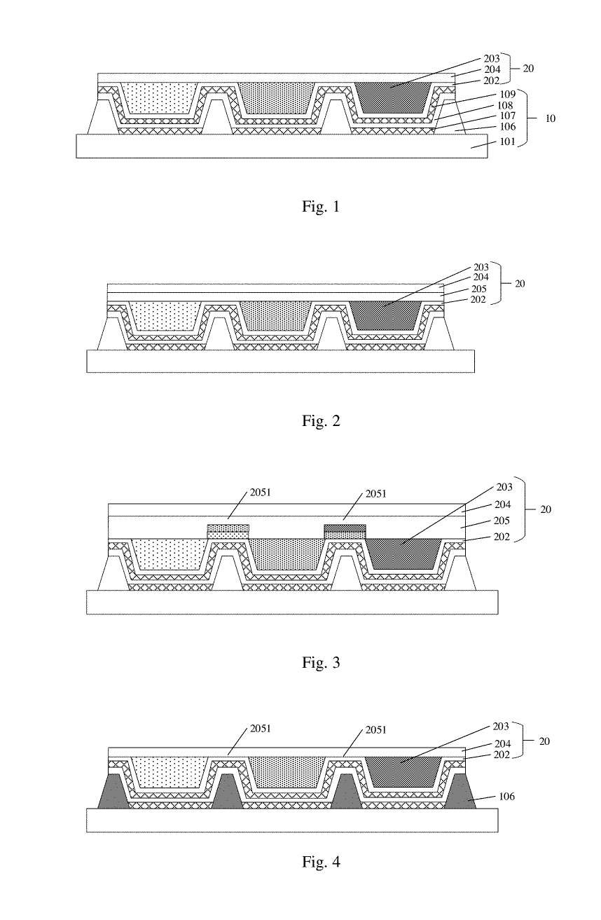

At least one embodiment of the present disclosure provides a display device. As illustrated in FIG. 1, the display device comprises a display panel 10 and a film package component 20 on the display panel 10; and the film package component 20 comprises a first water blocking material layer 202 on the display panel 10, a color filter layer 203 on the first water blocking material layer 202, and a second water blocking material layer 204 on the color filter layer 203.

In another example of the embodiment, as illustrated in FIG. 2, the film package component 20 may further comprise a second planarization layer 205 between the color filter layer 203 and the second water blocking material layer 204, and/or a first planarization layer between the color filter layer 203 and the first water blocking material layer 202. The second planarization layer 205 and/or the first planarization layer can planarize uneven regions of the color filter layer 203 generated during manufacture processes.

In the embodiment, a material of the first water blocking material layer 202 may comprise, for example, an inorganic material or an organic material; and a material of the second water blocking material layer 204 may comprise, for example, an inorganic material or an organic material. In the embodiment, an inorganic material is used, and the inorganic material may comprise, for example, silicon nitride, silicon oxide, silicon oxynitride, titanium oxide, zirconium oxide, tantalum oxide, barium titanate, neodymium oxide, aluminum oxynitride, zirconium oxynitride, tantalum oxynitride, yttrium oxynitride, neodymium oxynitride or the like. These materials of the first water blocking material layer 202 and the second water blocking material layer 204 have an excellent water blocking property, and can effectively prevent moisture brought in manufacture processes of functional layers and moisture in the air from penetrating into the display panel 10. In the embodiment, a material of the second planarization layer 205 and/or the first planarization layer may comprise, for example, a transparent organic material, such as polyimide (PI), epoxy resin or the like, which is not limited in the embodiment.

In the embodiment, a thickness of the first water blocking material layer 202 may range, for example, from 100 nm to 1000 nm, and for example, range from 500 nm to 600 nm. The second water blocking material layer 204 may be, for example, 200 nm-300 nm thicker than the first water blocking material layer 202, and a thickness of the second water blocking material layer 204 may range, for example, from 300 nm to 1200 nm, and for example, range from 700 nm to 800 nm. Therefore, the second water blocking material layer 204 can achieve the effect of blocking external moisture better. In the embodiment, a thickness of the color filter layer 203 may range, for example, from 1 μm to 3 μm, which may be different depending on actual situations such as the material of the color filter layer 203 and so on. A thickness of the second planarization layer 205 and/or the first planarization layer may be different, for example, depending on actual situations such as an unevenness extent of the color filter layer 203 and so on, which is not limited in the embodiment.

In the embodiment, as illustrated in FIGS. 3 and 4, the color filter layer 203 may comprise, for example, a plurality of color filers of different colors in a same layer (color filers of three different colors are illustrated in the figure), and an interval 2051 is between the color filers of different colors. In the embodiment, as illustrated in FIG. 3, a stack layer of color filers of at least two colors is at a position of the interval 2051 between the color filers of different colors; alternatively, as illustrated in FIG. 4, the position of the interval 2051 between the color filers of different colors corresponds to an opaque portion of a pixel definition layer 106 of the display panel. In the embodiment, the above structure in the interval 2051 between the color filers of different colors can prevent the display panel 10 from leaking light at the interval 2051 of the color filter layer 203, and therefore improve the display effect of the display panel 10.

In the embodiment, the color filter layer 203 may comprise, for example, a red color filter, a green color filter, and a blue color filter, which can be formed using a color resin material, for example, a color resin material having a photosensitive property. Therefore, the display panel 10 can emit light of three colors of red, green, and blue after white light emitted by the display panel 10 passes through the film package component 20.

In the embodiment, as illustrated in FIG. 3, the stack layer of color filers of at least two colors comprises two color filters of two different colors and is at the position of the interval 2051 of the color filter layer 203, and the two different colors are colors of two color filters that are adjacent to the interval 2051. For example, a stack layer of color filers of red and green is at a position of an interval between a red color filter and a green color filter; a stack layer of color filers of red and blue is at a position of an interval between a red color filter and a blue color filter; and a stack layer of color filers of green and blue is at a position of an interval between a green color filter and a blue color filter. Therefore, the plurality of color filters in the color filter layer 203 of the film package component 20 and the color filters at the position of the intervals adjacent thereto can be simultaneously formed, and therefore the manufacture process of the film package component 20 is simplified and the manufacturing cost is reduced.

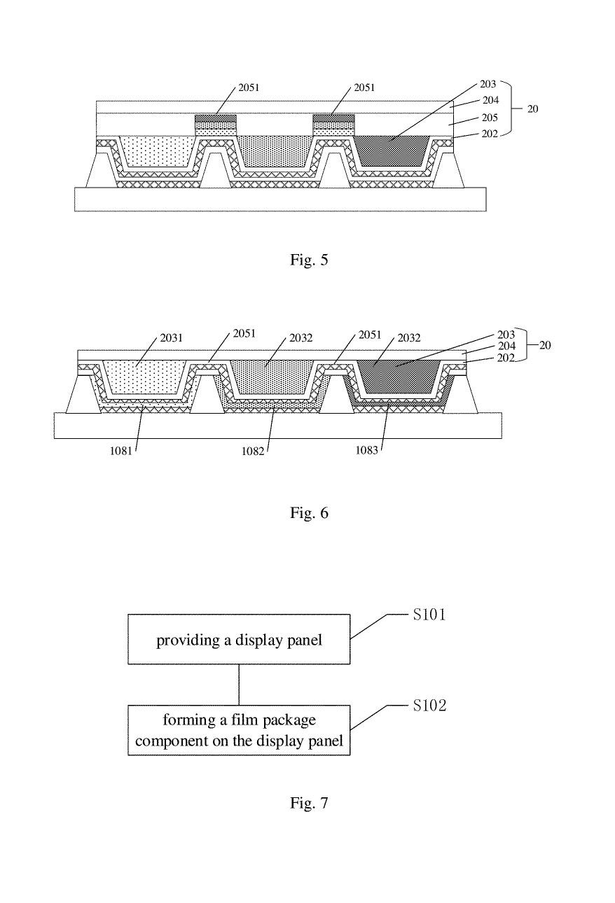

For another example, as illustrated in FIG. 5, a stack layer of color filters of three colors may be at the position of the interval 2051 of the color filter layer 203. For example, where the color filter layer 203 comprises a red color filter, a green color filter, and a blue color filter, a stack layer of a red color filter, a green color filter, and a blue color filter is at the position of the interval 2051 of the color filter layer 203. Therefore, the film package component 20 can achieve a better effect of preventing light leakage, so that the display panel 10 can achieve better display quality.

In the embodiment, the film package component may further comprise a transparent ultraviolet curing layer on the second water blocking material layer 204, and the transparent ultraviolet curing layer can protect the film package component and the display panel. In the embodiment, a material of the transparent ultraviolet curing layer may comprise, for example, a transparent resin material or the like, which is not limited in the embodiment.

In the embodiment, the display panel 10 may be, for example, an OLED display panel. As illustrated in FIG. 1, the OLED display panel may comprise functional structures such as a pixel definition layer 106, an anode layer 107, a light emitting layer 108, a cathode layer 109 and so on. In other examples, according to requirements, a hole injection layer, a hole transport layer, and so on may be further comprised between the anode layer and the light emitting layer, and an electron injection layer, an electron transport layer, and so on may be further comprised between the cathode layer and the light emitting layer. For example, driving circuits may be further formed on a substrate 101 to actively drive the OLEDs, and the driving circuit may comprise a gate line, a data line, a power line, a driving transistor, a switching transistor, a storage capacitor, and so on, which is not limited in the embodiment of the present disclosure.

The light emitting layer 108 of the OLED display panel may be, for example, a white light emitting layer; or as illustrated in FIG. 6, the light emitting layer may comprise a plurality of color light emitting layers, and for example, comprise a red light emitting layer 1081, a green light emitting layer 1082, and a blue light emitting layer 1083. Where the light emitting layer 108 is the white light emitting layer, white light emitted by the display panel 10 passes through the color filter layer 203 of the film package component 20, and color of the light emitted can be changed to be the same as the color of the color filter layer 203. For example, where the color filter layer 203 comprises the red color filter, the green color filter and the blue color filter, the display panel 10 can emit light of three colors of red, green and blue. The display panel 10 can be used, for example, in a VR (Virtual Reality) display device, an AR (Augmented Reality) display device or the like. In the embodiment, as illustrated in FIG. 6, where the light emitting layer comprises a plurality of color light emitting layers, and for example, comprises the red light emitting layer 1081, the green light emitting layer 1082, and the blue light emitting layer 1083, the color of each color light emitting layer of the display panel 10 respectively corresponds to the color of each color filter in the color filter layer of the film package 20, that is, the red light emitting layer 1081 corresponds to a red color filter 2031, the green light emitting layer 1082 corresponds to a green color filter 2032, and the blue light emitting layer 1083 corresponds to a blue color filter 2033. Therefore, light of three colors of red, green, and blue emitted by the display panel 10 passes through the color filter layer 203 of the film package component 20, the color of the emitted light can be more pure, and therefore the display quality of the display panel 10 can be improved.

The display device provided by the embodiment comprises the film package component, the interval between color filters in the color filter layer of the film package component is small, and in some examples, a light leakage prevention design at the position of the interval between color filters of different colors is provided, for example, a stack layer of color filters of different colors is provided at the position of the interval; alternatively, the position of the interval corresponds to an opaque portion of a pixel definition layer of the display panel. Therefore, the film package component provided by the embodiment can achieve a better filtering effect, and can alleviate light reflection of the surface of the display panel, and therefore the display panel can exhibit a good display effect without attaching a polarizer; in addition, the absence of the polarizer also contributes to a thin design of the display device.

At least one embodiment of the present disclosure provides a manufacture method of a display device. As illustrated in FIG. 7, the method comprises steps S101-S202.

Step S101: providing a display panel.

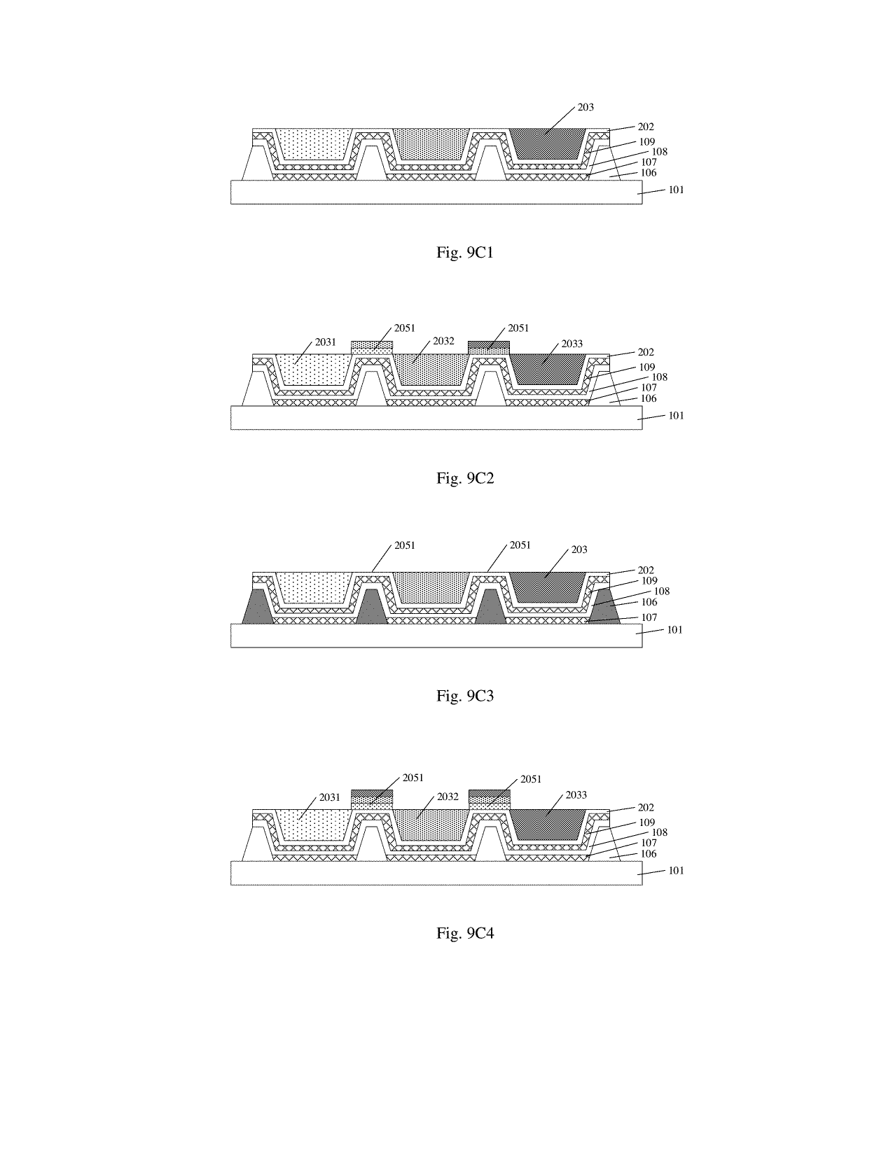

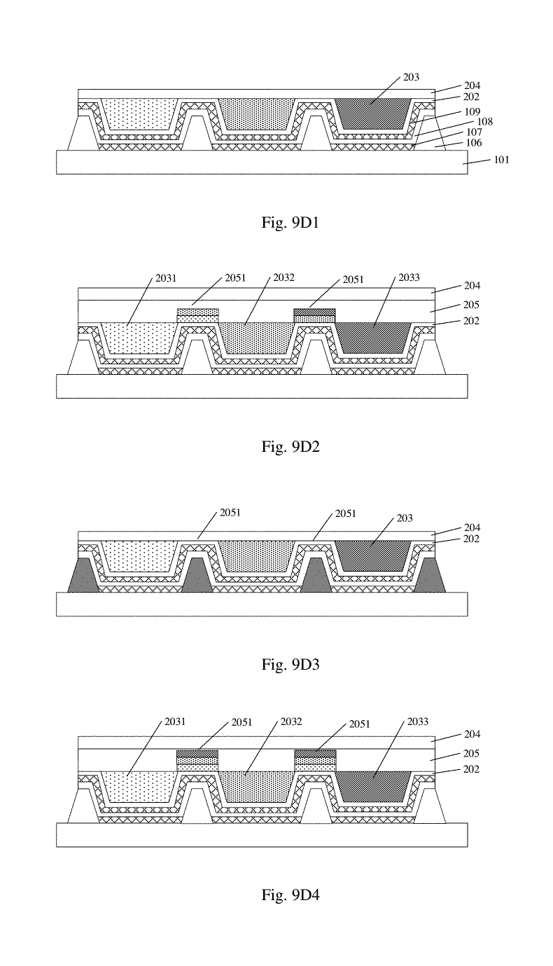

In the embodiment, as illustrated in FIG. 9A, the display panel may be, for example, an OLED display panel. The display panel may comprise, for example, a pixel definition layer 106, an anode layer 107, a light emitting layer 108, a cathode layer 109 and so on, which are sequentially formed on a substrate 101. For example, functional structures (not illustrated in the figure) such as gate lines, data lines, power lines, driving transistors, switching transistors, storage capacitors, and so on may also be formed on the substrate 101, which is not limited in the embodiment. In the embodiment, the light emitting layer 108 may be a white light emitting layer or comprise a plurality of color light emitting layers. The light emitting layer 108 may be formed by, for example, a vacuum evaporation method using a fine metal mask, an inkjet printing method or the like. The specific forming method of each functional layer is not limited in the embodiment.

Step S202: forming a film package component on the display panel.

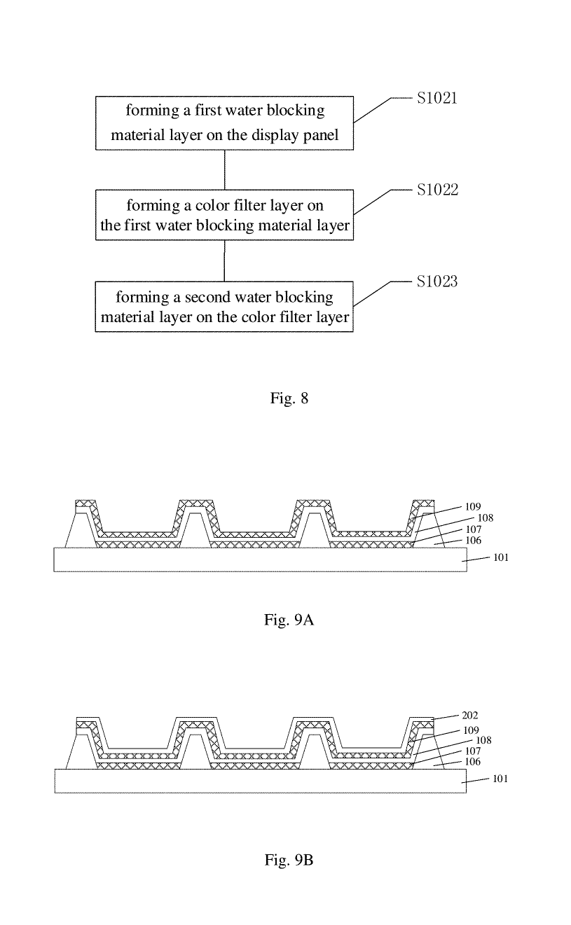

In the embodiment, the film package component may comprise, for example, a first water blocking material layer, a color filter layer, and a second water blocking material layer. In an example of the embodiment, as illustrated in FIG. 8, forming the film package component may comprise steps S2021-S2023.

Step S2021: forming a first water blocking material layer on the display panel.

In the embodiment, as illustrated in FIG. 9B, a first water blocking material layer 202 is first formed on the display panel. A material of the first water blocking material layer 202 may comprise, for example, an inorganic material or an organic material. The inorganic material is used in the embodiment. The inorganic material may comprise, for example, silicon nitride, silicon oxide, silicon oxynitride, titanium oxide, zirconium oxide, tantalum oxide, barium titanate, neodymium oxide, aluminum oxynitride, zirconium oxynitride, tantalum oxynitride, yttrium oxynitride, neodymium oxynitride or the like, which have an excellent water blocking property and can effectively prevent moisture brought during subsequent formation processes of other functional layers from penetrating into the display panel. In the embodiment, the first water blocking material layer 202 may be formed by, for example, a chemical vapor deposition method, a physical vapor deposition method, a coating method, or the like. A forming thickness of the first water blocking material layer 202 may range, for example, from 100 nm to 1000 nm, and for example, range from 500 nm to 600 nm.

Step S2022: forming a color filter layer on the first water blocking material layer.

In the embodiment, as illustrated in FIG. 9C1, after the first water blocking material layer 202 is formed, a color filter layer 203 is formed on the first water blocking material layer 202. In the embodiment, the color filter layer 203 may be formed by a photolithography method using a color resin material, or formed by an inkjet printing method using an organic pigment material. The inkjet printing method may be performed in an inert gas (for example, nitrogen) environment, and may be combined with a high-precision alignment system, for example. This environment can avoid the moisture bringing during the inkjet printing process of the color filter layer. The inkjet printing method also has advantages of high inkjet precision, adjustable inkjet position, adjustable inkjet quality and so on. For example, where the color filter layer 203 comprises a plurality of color filters of different colors, forming the color filters by the inkjet printing method can effectively adjust the interval between the color filters, so that the interval between the color filters formed by the inkjet printing method can be smaller, and therefore the filtering effect of the color filter layer can be better. In the embodiment, a forming thickness of the color filter layer 203 may range, for example, from 1 μm to 3 μm, and for example, the thickness is 1.5 μm, 2 μm or the like. The thickness may be selected, for example, according to the material of the color filter layer 203.

Step S2023: forming a second water blocking material layer on the color filter layer.

In the embodiment, as illustrated in FIG. 9D1, after the color filter layer 203 is formed, a second water blocking material layer 204 is formed on the color filter layer 203. In the embodiment, a material of the second water blocking material layer 204 may comprise, for example, an inorganic material or an organic material. In the embodiment, the inorganic material is used. The inorganic material may comprise any suitable material such as silicon nitride, silicon oxide, silicon oxynitride or the like. These materials have an excellent water blocking property and can effectively prevent moisture in the air from penetrating into the color filter layer 203 and the display panel. In the embodiment, the second water blocking material layer 204 may be formed by, for example, a chemical vapor deposition method, a physical vapor deposition method, a coating method or the like, and the formed second water blocking material layer 204 may be, for example, 200 nm-300 nm thicker than the first water blocking material layer 202. In the embodiment, a forming thickness of the second water blocking material layer 204 may range, for example, from 300 nm to 1200 nm, and for example, range from 700 nm to 800 nm, so that the second water blocking material layer 204 can achieve the effect of blocking external moisture better.

In another example of the embodiment, after the second water blocking material layer 204 is formed, for example, a transparent ultraviolet curing layer may further be formed on the second water blocking material layer 204 to protect the film package component and the display panel. In the embodiment, a material of the transparent ultraviolet curing layer may comprise, for example, a transparent resin material or the like, which is not limited in the embodiment.

In an example of the embodiment, the manufacture method of a display device may further comprise a step of forming a second planarization layer 205 between the color filter layer 203 and the second water blocking material layer 204, and/or forming a first planarization layer between the color filter layer 203 and the first water blocking material layer 202. For example, a step of forming the first planarization layer on the first water blocking material layer 202 is added after the step S2021, and then the color filter layer 203 is formed on the first planarization layer, so that the first planarization layer is formed between the color filter layer 203 and the first water blocking material layer 202; alternatively, a step of forming the second planarization layer 205 on the color filter layer 203 is added after the step S2022, and then forming the second water blocking material layer 204 on the second planarization layer 205, so that the second planarization layer 205 is formed between the color filter layer 203 and the second water blocking material layer 204. In the embodiment, a material of the second planarization layer 205 and/or the first planarization layer may comprise, for example, a transparent organic material, such as polyimide (PI), epoxy resin and so on, and a forming thickness of the second planarization layer 205 and/or the first planarization layer may be selected, for example, according to actual situations such as an unevenness extent of the color filter layer 203 and so on, which is not limited in the embodiment.

In the embodiment, as illustrated in FIG. 9C2, in the step S2022, when the color filter layer 203 is formed on the first water blocking material layer 202, the formed color filter layer may comprise, for example, a plurality of color filters of different colors having intervals 2051, and a stack layer of color filters of at least two colors is formed at a position of the interval 2051; alternatively, as illustrated in FIG. 9C3, the interval 2051 between color filters may be formed, for example, corresponding to an opaque portion of the pixel definition layer 106 of the display panel. In the embodiment, the above structures in the interval 2051 between color filters can prevent the display panel from leaking light at the interval 2051 of the color filter layer 203, and therefore improve the display effect of the display panel.

In the embodiment, as illustrated in FIG. 9C2, the color filter layer may comprise, for example, a red color filter 2031, a green color filter 2032, and a blue color filter 2033, the stack layer of color filters of at least two colors comprises two color filters of two different colors and is formed at a position of the interval 2051, and the two different colors are, for example, colors of two color filters that are adjacent to the interval 2051. For example, a stack layer of a red color filter and a green color filter may be formed at a position of an interval between the red color filter and the green color filter; a stack layer of a red color filter and a blue color filter may be formed at a position of an interval between the red color filter and the blue color filter; and a stack layer of a green color filter and a blue color filter may be formed at a position of an interval between the green color filter and the blue color filter. Therefore, the plurality of color filters in the color filter layer of the film package component and the color filters at the position of the interval adjacent thereto can be simultaneously formed, and therefore the manufacture process of the film package component can be simplified. In the embodiment, as illustrated in FIG. 9C4, for example, a stack layer of color filters of three colors may be formed at the position of the interval 2051 between the color filters of different colors. For example, where the color filter layer comprises the red color filter 2031, the green color filter 2032, and the blue color filter 2033, a stack later of a red color filter, a green color filter, and a blue color filter may be formed at the position of the interval 2051 in the color filter layer. Therefore, the film package component can achieve a better effect of preventing light leakage, and improve the display quality of the display panel.

In an example of the embodiment, where the color filter layer comprises a plurality of color filters of different colors having intervals, and a stack layer of color filters of at least two colors is at a position of the interval between the color filters of different colors, after the color filter layer described above is formed, a second planarization layer may further be formed on the color filter layer, and then a second water blocking material layer is formed on the second planarization layer. For example, as illustrated in FIG. 9D2, the stack layer of color filters of at least two colors comprises two color filters of two different colors and is formed at a position of an interval 2051 between color filters of different colors, and then a second planarization layer 205 is formed on the color filter layer. A forming thickness of the second planarization layer 205 may be, for example, greater than a thickness of the stack layer of color filters formed at the position of the interval 2051, and therefore an upper surface of the second planarization layer 205 is on a same plane to facilitate a subsequent formation of the second water blocking material layer 204 on the second planarization layer 205. For another example, as illustrated in FIG. 9D4, a stack layer of color filters of three colors is formed at the position of the interval 2051 between color filters of different colors, and then the second planarization layer 205 is formed on the color filter layer. The thickness of the second planarization layer 205 may be adjusted according to a thickness of the color filter layer and a thickness of the stack layer of the color filters at the position of the interval 2051, so that the upper surface of the second planarization layer 205 can be on the same plane, which facilitates the subsequent formation of the second water blocking material layer 204 on the second planarization layer 205. In the embodiment, as illustrated in FIG. 9D3, where the interval 2051 of the color filter layer is formed at a position corresponding to an opaque portion of the pixel definition layer 106 of the display panel, in the case that the flatness of the color filter layer is within an acceptable range, for example, the second water blocking material layer 204 can be directly formed on the color filter layer 203. In the embodiment, whether or not the second planarization layer 205 is formed can be selected, for example, according to actual situations such as the flatness of the color filter layer 203 and so on.

In the embodiment, where the light emitting layer 108 of the display panel is formed to be the white light emitting layer, white light emitted by the display panel passes through the color filter layer of the film package component, and color of the light emitted can be changed to be the same as the color of the color filter layer. For example, where the color filter layer is formed to comprise the red color filter, the green color filter and the blue color filter, the display panel can emit light of three colors of red, green and blue. The display panel can be used, for example, in a VR (Virtual Reality) display device, an AR (Augmented Reality) display device or the like. In the embodiment, where the light emitting layer 108 of the OLED display panel comprises a plurality of color light emitting layers, and for example, comprises the red light emitting layer, the green light emitting layer, and the blue light emitting layer, each color filter of different colors in the color filter layer of the film package component is formed to correspond to each color light emitting layer of corresponding color of the display panel, respectively. Therefore, light of three colors of red, green, and blue emitted by the display panel respectively passes through the corresponding color filters of the film package component, the color of the emitted light can be more pure, and therefore the display quality of the display panel can be improved.

The manufacture method of a display device provided by the embodiment comprises forming the film package component on the display panel, the interval between color filters in the color filter layer of the film package component is small, and in some examples, the stack layer of color filters of different colors is provided at the position of the interval; alternatively, the position of the interval corresponds to an opaque portion of a pixel definition layer of the display panel. Therefore, the film package component provided by the embodiment can achieve a better filtering effect, and can alleviate the light reflection of the surface of the display panel, and therefore the display panel can exhibit a good display effect without attaching a polarizer; in addition, the absence of the polarizer also contributes to a thin design of the display device.

The following statements should be noted:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness of a layer or a structure may be enlarged or reduced. However, it should be understood that, in the case in which a component or element such as a layer, film, area, substrate or the like is referred to be “on” or “under” another component or element, it may be directly on or under the another component or element or a component or element is interposed therebetween.

(3) In case of no conflict, features in one embodiment or in different embodiments can be combined to obtain new embodiments.

The above descriptions are only specific embodiments of the present disclosure, but the protection scope of the present disclosure is not limited thereto, those skilled in the art may make some improvements and modifications within the technical scope of the present disclosure, and the improvements and modifications should be within the protection scope of the present disclosure. Therefore, the protection scope of the present disclosure should be determined by the protection scope of the claims.

What is claimed is:

1. A display device, comprising:
a display panel, and
a film package component on the display panel;
wherein the film package component comprises:
a first water blocking material layer on the display panel,
a color filter layer on the first water blocking material layer, and
a second water blocking material layer on the color filter layer.

2. The display device according to claim 1, wherein a material of the first water blocking material layer comprises an inorganic material; and/or
a material of the second water blocking material layer comprises an inorganic material.

3. The display device according to claim 2, wherein the inorganic material comprises silicon nitride, silicon oxide, silicon oxynitride, titanium oxide, zirconium oxide, tantalum oxide, barium titanate, neodymium oxide, aluminum oxynitride, zirconium oxynitride, tantalum oxynitride, yttrium oxynitride or neodymium oxynitride.

4. The display device according to claim 1, wherein a thickness of the first water blocking material layer ranges from 100 nm to 1000 nm.

5. The display device according to claim 4, wherein the second water blocking material layer is 200 nm-300 nm thicker than the first water blocking material layer.

6. The display device according to claim 1, wherein a thickness of the color filter layer ranges from 1 μm to 3 μm.

7. The display device according to claim 1, wherein the color filter layer comprises a plurality of color filters of different colors in a same layer, and an interval is between color filters of different colors;
a stack layer of color filters of at least two colors is at a position of the interval; alternatively, the position of the interval corresponds to an opaque portion of a pixel definition layer of the display panel.

8. The display device according to claim 7, wherein the stack layer of color filters of at least two colors comprises two color filters of two different colors, and the two different colors are colors of two color filters that are adjacent to the interval.

9. The display device according to claim 1, wherein the display panel is an organic light emitting diode (OLED) display panel, and a light emitting layer of the OLED display panel is a white light emitting layer or comprises a plurality of color light emitting layers.

10. The display device according to claim 1, wherein the film package component further comprises a first planarization layer between the color filter layer and the first water blocking material layer, and/or
a second planarization layer between the color filter layer and the second water blocking material layer.

11. A manufacture method of a display device, comprising:
providing a display panel, and
forming a film package component on the display panel;
wherein forming the film package component comprises:
forming a first water blocking material layer on the display panel,
forming a color filter layer on the first water blocking material layer, and
forming a second water blocking material layer on the color filter layer.

12. The manufacture method of a display device according to claim 11, further comprising:
forming a first planarization layer between the color filter layer and the first water blocking material layer, and/or
forming a second planarization layer between the color filter layer and the second water blocking material layer.

13. The manufacture method of a display device according to claim 11, wherein the color filter layer is formed by an inkjet printing method.

14. The manufacture method of a display device according to claim 11, wherein forming the color filter layer comprises forming a plurality of color filters of different colors, and an interval is between color filters of different colors;
forming a stack layer of color filters of at least two colors at a position of the interval; alternatively, the interval is formed at a position corresponding to an opaque portion of a pixel definition layer of the display panel.

15. The manufacture method of a display device according to claim 14, wherein the color filter layer comprises a red color filter, a green color filter and a blue color filter, the stack layer of color filters of at least two colors comprises two color filters of two different colors and is formed at the position of the interval, the two different colors are colors of two color filters that are adjacent to the interval, and the stack layer of color filters and the two color filters that are adjacent to the interval are simultaneously formed.

16. The display device according to claim 2, wherein the film package component further comprises a first planarization layer between the color filter layer and the first water blocking material layer, and/or
a second planarization layer between the color filter layer and the second water blocking material layer.

17. The display device according to claim 3, wherein the film package component further comprises a first planarization layer between the color filter layer and the first water blocking material layer, and/or
a second planarization layer between the color filter layer and the second water blocking material layer.

18. The display device according to claim 7, wherein the film package component further comprises a first planarization layer between the color filter layer and the first water blocking material layer, and/or
a second planarization layer between the color filter layer and the second water blocking material layer.
